(19) United States
(12) Patent Application Publication
(10) Pub. No.: US 2009/0075459 A1
(43) Pub. Date: Mar. 19, 2009

(54) Apparatus and method for picking-up semiconductor dies

(75) Inventors: Yasushi Sato, Higashiyamato-shi (JP); Okito Umehara, Tachikawa-shi (JP); Akio Katsuro, Higashimurayama-shi (JP); Shinichi Sasaki, Higashiyamato-shi (JP)

Correspondence Address: QUINN EMANUEL;KODA & ANDROLIA, 865 S. FIGUEROA STREET, 10TH FLOOR, LOS ANGELES, CA, 90017, US

(73) Assignee: Kabushiki Kaisha Shinkawa

(21) Appl. No.: 12/231,752

(22) Filed: Sep. 5, 2008

Related U.S. Application Data
(60) Provisional application No. 60/967,609, filed on Sep. 6, 2007.

(51) Int. Cl. H01L 21/304; H01L 21/67

(52) U.S. Cl. 438/464; 29/25.01; 257/E21.238

(57) ABSTRACT

A die pick-up apparatus and method using a die stage having an adherence surface, a suction window formed in the adherence surface and larger than a semiconductor die to be picked up, and a cover plate that slides along the adherence surface and opens and closes the suction window. When picking up the semiconductor die, the surface of the cover plate is caused to be closely contacted to a dicing sheet that is attached to the die so that the die is within the boundary of the upper surface of the cover plate that closes the suction window, and then the dicing sheet is sequentially peeled off as, while the die is being suctioned by a collet, the cover plate gradually slides to sequentially open the suction window and allow the dicing sheet to be suctioned into the opened suction window.

### BACKGROUND OF THE INVENTION

The present invention relates to structures of a die pick-up apparatus for picking up semiconductor dies and to methods for picking up semiconductor dies.

Semiconductor dies are typically produced by dicing a wafer of 6 or 8 inches in diameter into dies of a predetermined size. When dicing a wafer, an adhesive dicing tape is applied on the back side of the wafer so as to prevent the produced semiconductor dies from falling apart, and then the wafer is cut from the other (front) side using, for example, a dicing saw. At this time, the dicing tape applied on the back side of the wafer is slightly cut on its surface but not entirely cut off, and the semiconductor dies are held and left on the tape. Then, the individual semiconductor dies are picked up one by one from the dicing tape and transferred to a subsequent step such as a die bonding step.

Conventionally, a method using a push-up needle is wildly employed for picking up semiconductor dies from an adhesive dicing tape (see FIG. 15 of Japanese Patent No. 3209736, for example). According to this method, semiconductor dies are picked up using a collet in such a manner that a semiconductor die is pushed upward in its center by a push-up needle under a dicing sheet on which a tensile force is exerted toward its periphery while the semiconductor die is suctioned by a collet, and thus the semiconductor die is removed from the adhesive dicing sheet by the tensile force exerted to the dicing sheet.

However, this method that uses a push-up needle has become less suitable for picking up thin semiconductor dies of recent years, because the method poses a problem that the pushing up can break the semiconductor dies as the dies become thinner.

For this reason, methods have been proposed with which semiconductor dies are removed and picked up from an adhesive dicing sheet without requiring the use of a push-up needle. For example, Japanese Patent No. 3209736 proposes a method including: placing a semiconductor die to be picked up over a suction hole in a die stage having a plurality of suction holes; producing vacuum in the plurality of suction holes to deform a dicing sheet by suctioning the sheet into the suction holes while the semiconductor die is suction-held by a collet; removing the dicing sheet corresponding to the suction hole from the semiconductor die; and then removing the remaining part of the dicing sheet from the semiconductor die by moving the die stage horizontally or rotationally (see FIG. 1 through FIG. 4 of Japanese Patent No. 3209736).

Japanese Patent No. 3209736 proposes another method. This method uses a die stage in which a protrusion is formed on a surface of the die stage, having a width narrower than that of a semiconductor die to be picked up, and a suction hole is provided in a portion of the surface of the stage that surrounds the protrusion; and with the use of this die stage, the method takes the steps of: mounting the semiconductor die to be picked up on the protrusion when picking up the semiconductor die such that the die to be picked up sticks out of the protrusion, and moving the protrusion in parallel with the surface of the die stage while suctioning air between a dicing sheet and the surface of the die stage from the suction hole, thereby peeling the dicing sheet from the semiconductor die (see FIG. 9 and FIG. 10 of Japanese Patent No. 3209736).

The method disclosed in Japanese Patent No. 3209736 is to peel the dicing tape from the semiconductor die by producing vacuum in the suction hole to suction the dicing tape into the suction holes. However, once peeled off from the semiconductor die, the dicing tape covers the suction hole, and consequently it is not possible to suction the air around the suction hole after peeling a portion of the dicing tape immediately above the suction hole. Thus, while the portion of the dicing sheet immediately above the suction hole can be peeled off by the suctioning, a portion of the dicing sheet covering around the suction hole cannot be peeled off by the vacuum suction through the suction hole and remains adhered to the semiconductor die (see FIG. 1 and FIG. 2 of Japanese Patent No. 3209736). On the other hand, in a case in which the remaining portion of the dicing sheet is peeled off by moving the die stage, a smaller area of the remaining portion results in a smaller force exerted to the semiconductor die, thereby reducing the damage caused to the semiconductor die. However, in order to make the remaining portion after peeling off the dicing sheet through the suction hole smaller, the suction hole is required to be of a size corresponding to the size of the semiconductor die to be picked up. Suctioning the dicing sheet through such a large suction hole may, when adhesive force of the dicing sheet is large, produce a large force that is exerted to the semiconductor die, and such a large force may break or deform the semiconductor die, especially because semiconductor dies of recent years are made thin with less intensity. As described above, with the method disclosed in Japanese Patent No. 3209736, it is unable to control the force exerted to the semiconductor die during the peeling off of the dicing sheet, because a large force is applied to the semiconductor die during the suctioning when a large suction hole is used, and during the movement of the die stage when a small suction hole is used, and thus the method poses a problem that the semiconductor die can be damaged.

The other method disclosed in Japanese Patent No. 3209736 peels off the dicing sheet by suctioning the air between the dicing sheet and the surface of the die stage through a small suction hole provided only around the protrusion, and thus it is possible to control the force exerted to the semiconductor die due to the suctioning. However, in this method, as the protrusion moves, the dicing sheet that has been peeled off from the semiconductor die covers the suction hole at the portion where the protrusion moves, and thus an amount of air suctioned decreases gradually according to the movement of the protrusion (see FIG. 9 and FIG. 10 of Japanese Patent No. 3209736). On the other hand, the length of the peeling line along which the dicing sheet is peeled is determined based on the width of the protrusion that moves, the force required to peel the dicing sheet does not change according to the moving direction of the protrusion. Further, because an area of the cross section of a gap between the side of the protrusion and the dicing sheet taken vertically to the movement direction of the protrusion does not change according to the movement of the protrusion, an area of the cross section of a flow path through which the air flows into the gap due to the movement of the protrusion does not change as well. Therefore, as the suction hole is blocked by the dicing sheet along with the movement of the protrusion, the amount of the air suctioned gradually decreases, and in turn the degree of the vacuum between the protrusion and the dicing sheet is reduced, thereby gradually decreasing the peel off power. In addition, there is a case in which the semiconductor die cannot be picked up smoothly because the dicing sheet remains unpeeled on the end surface of the semiconductor die facing toward the direction in which the protrusion moves. In such a case, it is possible to increase the peeling force utilizing the tensile force exerted to the dicing sheet by increasing the height of the protrusion. However, there is a problem that the protrusion can be brought into contact with an adjacent semiconductor die to damage the semiconductor die when the adjacent semiconductor die is present in the direction in which the protrusion moves, and thus the direction in which the protrusion moves is limited.

### SUMMARY OF THE INVENTION

In view of the above problems, an object of the present invention is to provide a die pick-up apparatus and method for picking up a semiconductor die easily while controlling a force exerted to the semiconductor die during peeling off of a dicing sheet.

A die pick-up apparatus for picking up semiconductor dies according to the present invention suctions and holds a semiconductor die attached to a dicing sheet and picking up the semiconductor die using a collet, and it is comprised of
a die stage provided with an adherence surface that is adhered to a first surface of the dicing sheet facing away from a second surface of the dicing sheet to which the semiconductor die is attached;
a suction window that is formed in the adherence surface and is larger than a semiconductor die to be picked up; and
a cover plate for opening and closing the suction window, the cover plate being provided on the die stage such that a surface of the cover plate slides along the adherence surface,

wherein the pick-up apparatus, when picking up the semiconductor die,
causes the surface of the cover plate to closely contact the dicing sheet such that the semiconductor die to be picked up falls within the surface of the cover plate that closes the suction opening, and
slides the cover plate to sequentially open the suction window and suctioning the dicing sheet into the opened suction window while the semiconductor die to be picked up is suctioned by the collet, thus sequentially peeling the dicing sheet from the semiconductor die to be picked.

In the die handling system for picking up semiconductor dies according to the present invention, it is preferable that the cover plate be provided on the die stage so as to slide along the adherence surface and protrude from the adherence surface, and when picking up the semiconductor die, the cover plate be caused to slide while the surface of the cover plate that is closely in contact with the dicing sheet protrude from the adherence surface.

Further, it is also preferable that when picking up the semiconductor die, a first end of the cover plate be aligned with a first end of the semiconductor die to be picked up, the suction window be sequentially opened by the cover plate sliding from the first end of the semiconductor die to be picked up toward a second end of the semiconductor die to be picked up, and the dicing sheet be sequentially peeled off from the semiconductor die to be picked up by sequentially suctioning the dicing sheet into the suction window that has been opened from a first end side of the semiconductor die to be picked up.

It is also preferable in the die pick-up apparatus for picking up semiconductor dies according to the present invention that the suction window be substantially as wide as the semiconductor die to be picked up and extend linearly from a central portion of the die stage toward outside of the die stage, and the cover plate be a rectangular plate that is substantially as wide as the suction opening.

It is further preferable that a notch be formed at a corner of the cover plate between a first end surface that faces an interior of the die stage and a side surface extending in a direction in which the suction window extends.

It is still further preferable that a suction hole be formed in the die stage around the suction window in the adherence surface, and

when picking up the semiconductor die, the cover plate is caused to slide while a portion of the dicing sheet around the semiconductor die to be picked up is suctioned through the suction hole, and that a sealing unit for restricting air from coming into the die stage is provided on a sliding plane between the cover plate and the suction opening.

Further, it is also preferable that the die pick-up apparatus for picking up semiconductor dies according to the present invention be further provided with a slide mechanism for sliding the cover plate wherein the slide mechanism is comprised of:
a drive unit that is attached to a base body of the die stage on a side opposite from the adherence surface and drives a first link member provided within the die stage in a direction that the first link member is moved closer to and away from the adherence surface;
a guide rail that is provided within the die stage and extends in a direction which is substantially in parallel with the adherence surface and in which the suction window extends;
a slider to which the cover plate is connected and which is slidably provided on the guide rail; and
a second link member that is slidably provided within the die stage, connects the slider to the first link member, and converts a movement of the first link member moving closer to and away from the adherence surface into a movement of the slider moving along the guide rail, and wherein

when picking up the semiconductor die, the slide mechanism causes the cover plate to slide along the adherence surface by the first link member moving closer to and away from the adherence surface using the drive unit.

It is also preferable that the die pick-up apparatus for picking up semiconductor dies according to the present invention be further provided with a slide mechanism for sliding the cover plate, wherein the slide mechanism is comprised of:
a drive unit that is attached to a base body of the die stage on a side opposite from the adherence surface and drives a first link member provided within the die stage in a direction that the first link member is moved closer to and away from the adherence surface;
a piston that is provided within the die stage and moved closer to and away from the adherence surface;
a stopper that is provided within the die stage and restricts the movement of the piston moving closer to and away from the adherence surface;
a spring that connects the first link member to the piston in the direction closer to and away from the adherence surface and is compressed when the piston is brought into contact with the stopper;
a guide rail that is attached to the piston and extends in a direction which is substantially in parallel with the adherence surface and in which the suction window extends;
a slider to which the cover plate is connected and which is slidably provided on the guide rail; and
a second link member that is slidably attached to the piston, connects the slider to the first link member, and converts a movement of the first link member moving closer to and away from the adherence surface into a movement of the slider moving along the guide rail when the piston is brought into contact with the stopper, and wherein

when picking up the semiconductor die, the slide mechanism causes the cover plate to slide along the adherence surface after the cover plate protrudes from the adherence surface by the first link member moving closer to and away from the adherence surface using the drive unit.

It is also preferable that the die pick-up apparatus for picking up semiconductor dies according to the present invention be further provided with a slide mechanism for sliding the cover plate wherein the slide mechanism is comprised of:
a drive unit that is attached to a base body of the die stage on a side opposite from the adherence surface and drives a first link member provided within the die stage in a direction that the first link member is moved closer to and away from the adherence surface;
a guide rail that is provided within the die stage, extends along the direction in which the suction window extends, and includes an inclined surface that inclines toward the adherence surface;
a slider to which the cover plate is connected and which is slidably provided on the inclined surface of the guide rail; and
a second link member that is slidably provided within the die stage, connects the slider to the first link member, and converts a movement of the first link member moving closer to and away from the adherence surface into a movement of the slider moving along the inclined surface of the guide rail, and wherein
when picking up the semiconductor die, the slide mechanism causes the cover plate to slide along the adherence surface while causing the cover plate to protrude from the adherence surface by moving the first link member closer to the adherence surface using the drive unit.

Moreover, it is preferable for the die pick-up apparatus for picking up semiconductor dies according to the present invention that the inclined surface of the guide rail of the slide mechanism include a cam surface that faces and inclines toward the adherence surface from the central portion of the die stage to the direction in which the suction window extends, and a parallel surface that continues from the cam surface and extends in parallel with the adherence surface to the direction in which the suction window extends and that the second link member include a curved surface or a roller that is moved along shapes of the cam surface and the parallel surface of the guide rail on the adherence surface side.

It is also preferable that the die pick-up apparatus for picking up semiconductor dies according to the present invention be further provided with:
a die stage vertical drive mechanism that moves the die stage in a direction closer to and away from the dicing sheet; and
a wafer holder horizontal drive unit that moves a wafer holder along a surface of the dicing sheet, the wafer holder being for retaining the dicing sheet to which the semiconductor die to be picked up is attached, and wherein

when picking up the semiconductor die, the surface of the cover plate is caused to closely contact with the dicing sheet by the die stage vertical drive mechanism, and die positioning is performed by the wafer holder horizontal drive unit so that the semiconductor die to be picked up falls within the surface of the cover plate closing the suction opening.

A method for picking up semiconductor dies according to the present invention picks up semiconductor dies that are attached to a dicing sheet using a die pick-up apparatus comprising:
a die stage provided with an adherence surface that is adhered to a first surface of the dicing sheet facing away from a second surface of the dicing sheet to which a semiconductor die to be picked up is attached;
a suction window that is formed in the adherence surface and is larger than the semiconductor die to be picked up;
a cover plate for opening and closing the suction window, the cover plate being provided on the die stage such that a surface of the cover plate slides along the adherence surface; and
a collet for picking up a semiconductor die, and

the method comprises
a die positioning step in which the surface of the cover plate is caused to closely contact with the dicing sheet such that the semiconductor die to be picked up falls within the surface of the cover plate that closes the suction opening, and
a dicing sheet peeling step in which the dicing sheet is sequentially peeled from the semiconductor die to be picked up by sliding the cover plate to sequentially open the suction window and suctioning the dicing sheet into the opened suction window while the semiconductor die to be picked up is suctioned by the collet.

In the method for picking up semiconductor dies according to the present invention, it is preferable that
the cover plate be provided on the die stage so as to slide along the adherence surface and protrude from the adherence surface, and
in the dicing sheet peeling step slide the cover plate while the surface of the cover plate is being protruded from the adherence surface.

It is, in the method of the present invention, also preferable that
the die positioning step align a first end of the cover plate with a first end of the semiconductor die to be picked up, and
the dicing sheet peeling step sequentially open the suction window by sliding the cover plate from the first end of the semiconductor die to be picked up toward a second end of the semiconductor die to be picked up and sequentially peel off the dicing sheet from the semiconductor die to be picked up by sequentially suctioning the dicing sheet into the suction window that has been opened from a first end side of the semiconductor die to be picked up.

The present invention advantageously provides a die pick-up apparatus and method for picking up semiconductor dies capable of picking up a semiconductor die easily while controlling a force exerted to the semiconductor die during peeling off of a dicing sheet from the die.

### BRIEF DESCRIPTION OF THE DRAWINGS

FIG. 1 is an explanatory diagram illustrating a wafer on a dicing sheet;

FIG. 2 is an explanatory diagram illustrating semiconductor dies on the dicing sheet;

FIGS. 3(a) and 3(b) are explanatory diagrams illustrating a configuration of a wafer holder;

FIG. 4 is an explanatory diagram illustrating a configuration of a die pick-up apparatus for picking up semiconductor dies of one embodiment according to the present invention;

FIG. 5 is a perspective view illustrating a die stage of the die pick-up apparatus for picking up semiconductor dies of the embodiment according to the present invention;

FIGS. 6(a) and 6(b) are explanatory diagrams illustrating a state of the die pick-up apparatus for picking up semiconductor dies of the embodiment according to the present invention before a cover plate of the die pick-up apparatus starts sliding;

FIGS. 7(a) and 7(b) are explanatory diagrams illustrating a state of the die pick-up apparatus for picking up semiconductor dies of the embodiment according to the present invention when the cover plate of the die pick-up apparatus starts sliding;

FIGS. 8(a) and 8(b) are explanatory diagrams illustrating a state of the die pick-up apparatus for picking up semiconductor dies of the embodiment according to the present invention while the cover plate of the die pick-up apparatus keeps sliding;

FIGS. 9(a) and 9(b) are explanatory diagrams illustrating a state of the die pick-up apparatus for picking up semiconductor dies of the embodiment according to the present invention when the cover plate of the die pick-up apparatus finishes sliding;

FIGS. 10(a) and 10(b) are explanatory diagrams illustrating a state of the die pick-up apparatus for picking up semiconductor dies of the embodiment according to the present invention in which a collet of the die pick-up apparatus picks up a semiconductor die and the cover plate returns to a closed position;

FIGS. 11(a) and 11(b) are explanatory diagrams illustrating a configuration of a die pick-up apparatus for picking up semiconductor dies of a different embodiment according to the present invention;

FIG. 12 is an explanatory diagram illustrating a configuration of a die v for picking up semiconductor dies of a different embodiment according to the present invention;

FIG. 13 is an explanatory diagram illustrating a state of the die v for picking up semiconductor dies of the different embodiment according to the present invention when a cover plate of the die pick-up apparatus starts sliding;

FIG. 14 is an explanatory diagram illustrating a state of the die pick-up apparatus for picking up semiconductor dies of the different embodiment according to the present invention when the cover plate of the die pick-up apparatus finishes sliding;

FIG. 15 is an explanatory diagram illustrating a configuration of a die pick-up apparatus for picking up semiconductor dies of the different embodiment according to the present invention;

FIG. 16 is an explanatory diagram illustrating a configuration of a die pick-up apparatus for picking up semiconductor dies of a further different embodiment according to the present invention;

FIG. 17 is an explanatory diagram illustrating a projecting operation of the cover plate of the die pick-up apparatus for picking up semiconductor dies of the further different embodiment according to the present invention; and

FIG. 18 is an explanatory diagram illustrating a sliding operation of the cover plate of the die pick-up apparatus for picking up semiconductor dies of the further different embodiment according to the present invention.

### DETAILED DESCRIPTION OF THE INVENTION

The preferred embodiments of the present invention will be described in detail below with reference to the accompanying drawings. Before describing a die pick-up apparatus for picking up semiconductor dies according to the present invention, an explanation will be given first on a wafer and a wafer holder.

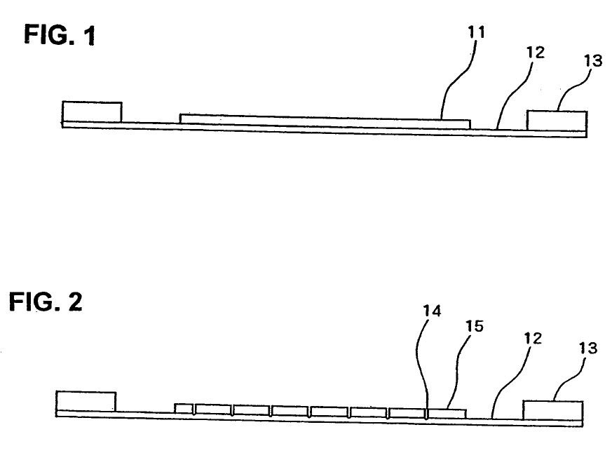

Referring to FIG. 1, a wafer 11 is applied with an adhesive dicing sheet 12 on a back side thereof, and the dicing sheet 12 is attached to a metal ring 13. The wafer 11 is handled while being attached to the metal ring 13 with the dicing sheet 12 therebetween as shown in the drawings. Then, as shown in FIG. 2, the wafer 11 is diced, in a dicing step, into semiconductor dies 15 from the other side using, for example, a dicing saw. Between each pair of the semiconductor dies 15 is a cutting gap 14 that is formed during the dicing, and while the cutting gap 14 reaches a part of the dicing sheet 12 through the semiconductor dies 15, the dicing sheet 12 is not totally cut apart, and the semiconductor dies 15 remain held on the dicing sheet 12.

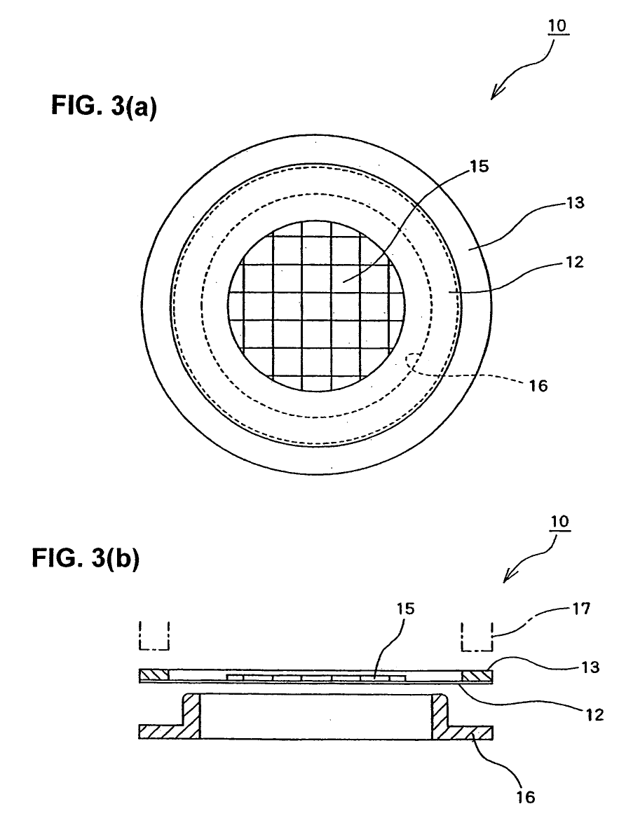

The semiconductor dies 15 attached to the dicing sheet 12 and the ring 13 in this manner is mounted on a wafer holder 10 as shown in FIGS. 3(a) and 3(b). The wafer holder 10 is provided with an annular expand ring 16 having a flange portion and ring retainers 17 that retain the ring 13 on the flange of the expand ring 16. The ring retainers 17 are driven close to and away from the flange of the expand ring 16 by a ring retainer drive unit that is not shown in the drawings. The inner diameter of the expand ring 16 is larger than the diameter of the wafer that includes the semiconductor dies 15, and the expand ring 16 has a predetermined thickness. The flange is on the outer circumference of the expand ring 16, and it faces away form the dicing sheet so to protrudes outwardly from the end surface of the expand ring 16. Further, the outer circumference of the expand ring 16 that is on the dicing sheet side is configured to have a curved surface so that it is possible to expand the dicing sheet 12 when the dicing sheet 12 is attached to the expand ring 16. Moreover, the wafer holder 10 is configured to move along the surface of the dicing sheet 12 by a wafer holder horizontal drive unit that is not shown in the drawings.

As shown in FIG. 3(b), the dicing sheet 12 to which the semiconductor dies 15 are attached is substantially flat, before being set in the expand ring 16.

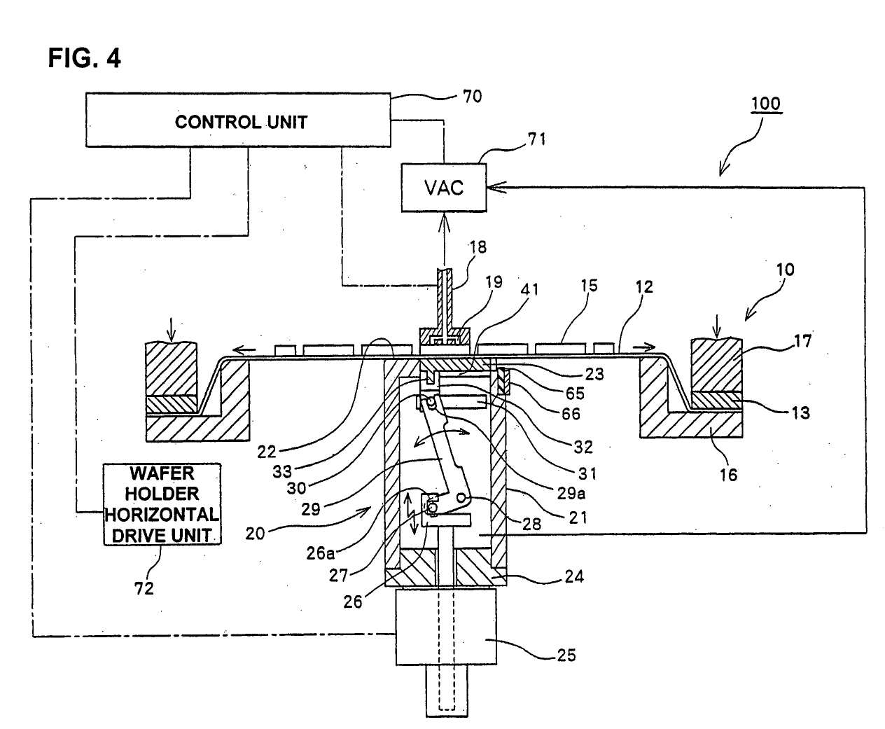

FIG. 4 is a diagram illustrating a configuration of a die pick-up apparatus 100 for picking up semiconductor dies, and it also illustrates a state in which the semiconductor dies 15 attached to the dicing sheet 12 is set in the die pick-up apparatus 100. In this state, the ring retainers 17 are lowered toward the ring 13 to hold the ring 13 between the retainers 17 and the flange of the expand ring 16. There is a difference in level or height between the upper surface of the expand ring 16 that is in contact with the dicing sheet 12 and the surface of the flange. Accordingly, when the ring 13 is pressed onto the surface of the flange, the dicing sheet 12 is stretched along the curved surface at the upper portion of the expand ring due to the height difference. As a result, a tensile force is exerted to the dicing sheet 12, which is fixed on the expand ring 16, radially from the center of the dicing sheet 12 toward the circumference. In addition, because the dicing sheet 12 is stretched due to the tensile force, the gap between the semiconductor dies 15 that are next to each other and attached to the dicing sheet 12 is also expanded.

The wafer holder 10 is attached with a wafer holder horizontal drive unit 72 that moves the wafer holder along a plane that corresponds to the dicing sheet. The wafer holder horizontal drive unit 72 drives the wafer holder 10 horizontally using, for example, a motor and a gear provided internally, and it can be one that moves the wafer holder 10 in an XY direction by a driving source which is an externally provided motor. Furthermore, a collet 18 is provided on the upper portion of the wafer holder 10 for moving the semiconductor dies 15 while suctioning. The collet 18 is provided, on its suction surface, with suction holes 19 for suctioning a semiconductor die 15, and each suction hole 19 is connected to a vacuum apparatus 71. Moreover, a die stage 20 is provided under the wafer holder 10. The die stage 20 is driven upward and downward, i.e. in a direction moving close to and away from the dicing sheet 12, by a die stage vertical drive mechanism that is not shown in the drawings.

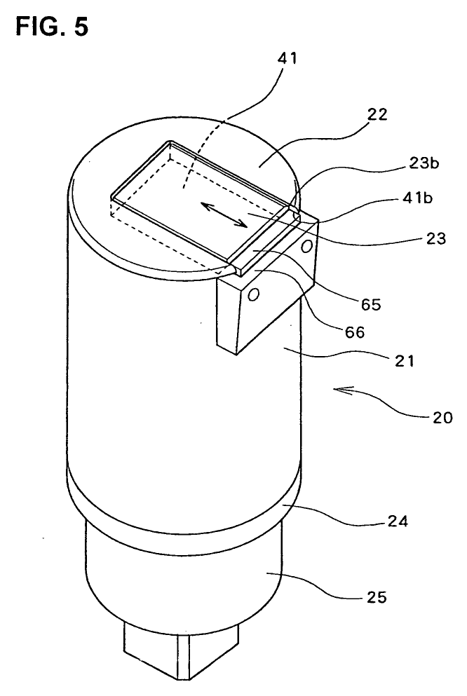

Referring to FIG. 5, the die stage 20 is comprised of a cylindrical housing 21 having on its upper surface an adherence surface 22 to which the dicing sheet 12 is adhered, a base body 24 that is provided on an opposite side of the housing 21 from the adherence surface 22, and a drive unit 25 that is attached to the base body 24 and drives a link mechanism provided inside the housing 21. The base body 24 of the die stage 20 is attached to a die stage fixing unit, not shown in the drawings, of the die pick-up apparatus.

The adherence surface 22 of the die stage 20 has a suction window 41 therein. The suction window 41 extends linearly and outwardly from the central portion of the die stage 20 and is substantially as wide as and longer than the semiconductor die to be picked up 15. Further, the die stage 20 is provided with a cover plate 23 that covers the suction window 41. The cover plate 23 is a rectangular plate, and the surface of the cover plate 23 is set so as to be substantially on the same plane as the adherence surface 22. The cover plate 23 is configured so as to be capable of sliding along a direction (see the arrow in FIG. 5) in which the suction window 41 extends. Moreover, as can be seen from the fact that the cover plate 23 is fitted in the suction window 41, the cover plate 23 is substantially as wide as the suction window 41 and substantially as wide as the semiconductor die to be picked up 15 and in addition, the cover plate 23 is longer than the semiconductor die to be picked up 15. The suction window 41 can be configured such that a step having a slit that communicates with the die stage 20 is provided within the suction window, as long as the suction window 41 is substantially as wide as the semiconductor die to be picked up 15 on the adherence surface 22. The side surface 23b of the cover plate 23 and the side surface 41b of the suction window together constitute a sliding plane.

A sealing member 65 is provided between the side surface 23b of the cover plate 23 and the side surface 41b of the suction window. The sealing member 65 restricts air coming along the sliding plane into the die stage through the suction window 41. The sealing member 65 is provided on the outer circumference of the die stage 20 such that the sealing member 65 covers a gap between the side surface 23b of the cover plate 23 and the side surface 41b of the suction window, and it is attached to the die stage 20 by a seal retainer 66 such that the seal retainer 66 wraps around the sealing member 65. As shown in FIG. 5, the sealing member 65 is provided such that the tip end of the sealing member 65 protrudes upward toward the adherence surface so as to be higher than the bottom surface of the cover plate 23, so that it can prevent the air from flowing into the die stage 20 through the gap between the bottom surface of the cover plate 23 and the side surface 23b of the cover plate 23 by being compressed when the cover plate 23 slides toward outside of the die stage 20. The sealing member 65 can be made of an elastic material such as rubber.

As shown in FIG. 4, a slide mechanism for sliding (moving) the cover plate 23 is provided within the die stage 20. The slide mechanism is comprised of: a first link member 26 that is driven in a direction closer to and away from with respect to the adherence surface 22 by a drive unit 25 mounted to the base body 24 of the die stage 20; a second link member 29 in a L-shape and attached rotatably to a pin 28 fixed to the housing 21; a pin 27 provided at a first end of the second link member 29 and fitted in an engaging groove 26a of the first link member 26 so as to connect the first link member 26 and the second link member 29; a guide rail 31 fixed to the housing 21 and extending in a direction which is parallel to the adherence surface 22 and along which the suction window 41 extends; a slider 32 slidably mounted to the guide rail 31; a pin 30 attached to the slider 32 and fitted in an engaging groove 29a formed in a second end of the second link member 29 so as to connect the slider 32 and the second link member 29; and a pin 33 that attaches the cover plate 23 to the slider 32.

Further, the housing 21 is connected to the vacuum apparatus 71 so as to be evacuated to produce a vacuum therein. The drive unit 25 can have any configuration as long as the first link member 26 can be operated to move closer to and away from the adherence surface 22. For example, the drive unit 25 can use a small motor and a cam working in combination to drive the first link member 26 up and down, and it can directly move the first link member 26 up and down by an electromagnetic force.

Referring to FIG. 4, the operation of the slide mechanism will be described below. When the first link member 26 is moved upward toward the adherence surface 22 of the die stage 20 by the drive unit 25, the engaging groove 26a of the first link member 26 is also moved upward toward the adherence surface 22. Then, when the engaging groove 26a is move upward, the pin 27 fitted in the engaging groove 26a is moved upward along with the engaging groove 26a. When the pin 27 is thus moved upward, the second link member 29 that has the pin 27 rotates about the pin 28 fixed to the housing 21; as a result, the engaging groove 29a at the second end of the second link member 29 is moved toward the outside of the die stage 20 which is the direction in which the suction window 41 extends (or is moved to the right in FIG. 4). With this movement of the engaging groove 29a of the second link member 29, the pin 30 fitted in the engaging groove 29a is also moved toward the outside of the die stage 20. Because the slider 32 having the pin 30 is provided so as to move or slide along the guide rail 31, when the pin 30 is moved toward the outside of the die stage 20 (or to the right in FIG. 4), the slider 32 moves or slides along the guide rail 31 toward the outside of the die stage 20 substantially in parallel with the adherence surface 22. The engaging groove 29a of the second link member 29 is U-shaped, and as a result, it absorbs the difference of amounts in movement between the movement of the engaging groove 29a caused by the rotation of the second link member 29 and the movement of the slider 32 provided with the pin 30 in parallel with the adherence surface 22 due to the difference in the directions. Then, when the slider 32 is moved along the guide rail 31 in parallel with the adherence surface 22, the cover plate 23 connected to the slider 32 via the pin 30 is moved with the slider 32 toward the outside of the die stage 20 along the guide rail 31 in parallel with the adherence surface 22, thereby the cover plate 23 is opened. When closing the cover plate 23, the first link member 26 is moved downward away from the adherence surface 22 by the drive unit 25, as a result, the second link member 29 and the slider 32 are moved in a direction opposite of the direction previously described to move the cover plate 23 inwardly from the outside of the die stage (or to the left in FIG. 4), thereby the cover plate 23 is closed.

As seen from the above, the slide mechanism converts, using the L-shaped second link member 29, the movement of the first link member 26 that operates in the direction closer to and away from the adherence surface 22 into the movement of the slider 32 that is moved in parallel with the adherence surface 22. Accordingly, it is possible to configure the slide mechanism in a compact form to be accommodated within the housing 21 of a cylindrical shape.

As shown in FIG. 4, the die pick-up apparatus 100 for picking up semiconductor dies is further provided with a control unit 70 that includes, among others, a CPU (Central Processing Unit). The drive unit 25, the vacuum apparatus 71, the collet 18, and the wafer holder horizontal drive unit 72 are connected to the die pick-up apparatus 100, and the drive units 25 and 72, the collet 18, and the vacuum apparatus 71 are respectively driven according to the instructions outputted from the control unit 70. In FIG. 4, single dashed lines represent signal lines connecting the control unit 70 with the drive units 25 and 72, the collet 18, and the vacuum apparatus 71, respectively. In addition, the die stage vertical drive mechanism that is not shown in the drawings is also connected to the control unit 70 and configured to drive the die stage 20 up and down according to the instruction from the control unit 70.

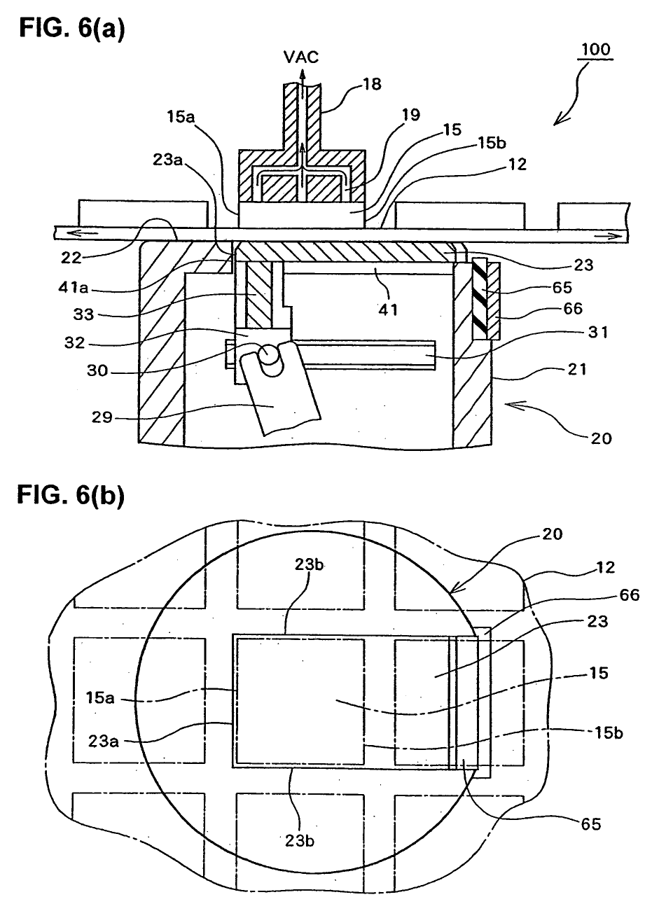

Now, referring to FIG. 6(a) through FIG. 10(b), the operation of picking up the semiconductor dies 15 from the dicing sheet 12 using the die pick-up apparatus 100 for picking up semiconductor dies will be described. The elements described with reference to FIG. 1 through FIG. 5 are designated by the same reference numerals and will not be explained here.

The control unit 70 starts a die positioning step. As shown in FIG. 6(a), the control unit 70 moves the wafer holder 10 in the parallel direction above a waiting position of the die stage 20 by the wafer holder horizontal drive unit 72 shown in FIG. 4. Then, the control unit 70 temporarily stops the parallel movement of the wafer holder 10 when the wafer holder 10 reaches a predetermined position on the waiting position of the die stage 20, and the control unit 70 moves the die stage 20 upward by the die stage vertical drive mechanism that is not shown in the drawings until the adherence surface 22 of the die stage 20 and the upper surface of the cover plate 23 are closely in contact with the lower surface of the dicing sheet 12. Once the adherence surface 22 of the die stage 20 and the upper surface of the cover plate 23 are closely contacted to the lower surface of the dicing sheet 12, the control unit 70 stops the upward movement of the die stage 20. Then, the control unit 70 adjusts a parallel position of the wafer holder 10 using again the wafer holder horizontal drive unit 72 so that the first end surface 23a of the cover plate 23 that faces the interior of the die stage reaches a position aligning with a first end 15a of the semiconductor die 15 to be picked up. Further, the control unit 70 adjusts the side surface of the semiconductor dies 15 to align with the side surface 23b of the cover plate 23. Because the cover plate 23 is substantially as wide as the semiconductor die 15 to be picked up, aligning one of the side surfaces 23b of the cover plate 23 with the side surface of the semiconductor dies 15 realizes the alignment between the both side surfaces of the semiconductor dies 15 and both of the side surfaces 23b of the cover plate 23. At this time, the dicing sheet 12 is being applied with a tensile force by the expand ring 16 of the wafer holder 10. Further, because the cover plate 23 is at a position that it closes the suction window 41, the first end surface 23a of the cover plate 23 is at a position at which the first end surface 23a is in contact with the first end surface 41a of the suction window 41 that faces the interior of the die stage, and the sealing member 65 is at an initial position where it protrudes upward toward the adherence surface from a plane flush with the bottom surface of the cover plate 23.

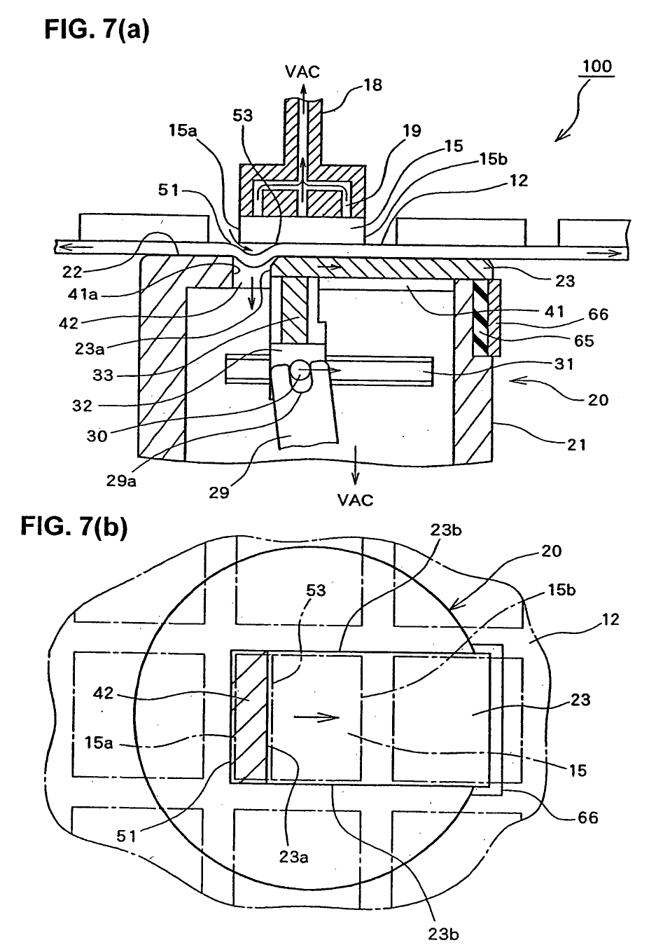

FIG. 6(b) is a plan view illustrating the adherence surface 22 of the die stage 20 and the upper surface of the cover plate 23, in which the dicing sheet 12 and the semiconductor dies 15 mounted thereon are shown by single dashed lines to clarify the positional relation. In FIG. 6(b), in order to distinguish between the semiconductor dies 15 and the cover plate 23 whose widths are both substantially the same, the cover plate 23 is shown slightly larger than the semiconductor dies 15. The same applies to FIG. 7(b) through FIG. 10(b).

As shown in FIG. 6(b), because the semiconductor dies 15 are substantially as wide as the cover plate 23, each of the semiconductor dies 15 comes at a position at which the first end 15a of the die aligns with the first end surface 23a of the cover plate 23, and the side surface of the semiconductor dies 15 aligns with both side surfaces 23b of the cover plate 23. Further, because the suction window 41 and the cover plate 23 are both longer in the sliding direction than the semiconductor dies 15, each of the semiconductor dies 15 is at a position at which the second end 15b of the semiconductor dies 15 is on the cover plate 23. Upon completion of the approach and contact of the die stage 20 to the lower surface of the dicing sheet and the positioning of the semiconductor dies 15, the control unit 70 finishes the positioning step.

Then, the control unit 70 moves the collet 18 to above the semiconductor 15 die to be picked up and activates the vacuum apparatus 71 to evacuate the suction holes 19 on the suction surface to produce a vacuum in the holes, thereby suctioning and holding the semiconductor die 15 to be picked up at this place.

As shown in FIG. 7(a) through FIG. 10(b), the control unit 70 starts a dicing sheet peeling step. As shown in FIGS. 7(a) and 7(b), the control unit 70 evacuates the housing 21 of the die stage 20 using the vacuum apparatus 71 to produce a vacuum therein. Because the sealing unit prevents the air from entering along the side surface 23b of the cover plate 23, the vacuum state is favorably maintained. Then, the control unit 70 moves the first link member 26 toward the adherence surface 22 using the drive unit 25 and moves the second link member 29 toward the outside of the die stage 20 (or to the right in FIG. 7(a). By this movement, the pin 30 fitted in the engaging groove 29a of the second link member 29 is moved toward the outside of the die stage 20, thereby causing the cover plate 23 connected to the pin 30 via the pin 33 to start opening toward the outside of the die stage 20.

As shown in FIGS. 7(a) and 7(b), when the cover plate 23 slides (to the right in FIG. 7(a)), the first end surface 23a of the cover plate 23 is separated from the first end surface 41a of the suction window 41 and the suction window 41 opens, thereby creating an suction opening 42 whose width is substantially the same as that of the semiconductor die 15 to be picked up. Because the interior of the housing 21 of the die stage 20 is in a vacuum state by the vacuum apparatus 71, the suction opening 42 suctions the dicing sheet into the housing 21. Moreover, the sealing member 65 is compressed by the moving cover plate 23 and blocks the gap between the cover plate 23 and the suction window 41, preventing the air from entering into the die stage 20 from outside. As a result, the degree of vacuum is maintained high within the housing 21. By this suctioning, the dicing sheet 12 deforms down into the suction opening 42 and a depression downward is formed in the dicing sheet 12. Then, by this deformation, the dicing sheet 12 starts to come off from the first end 15a side of the semiconductor die 15. When the dicing sheet 12 is peeled from the first end 15a side of the semiconductor die 15, the air comes into the gap 51 between the semiconductor die 15 and the dicing sheet 12 that is produced by the peeling. As a result, a difference in pressure is produced in the dicing sheet 12 between the semiconductor die 15 side and the suction opening 42 side that that has been evacuated, and the dicing sheet 12 is further suctioned into the suction opening 42 in the vacuum state. Then, the air comes into until it reaches a peel off line 53 that is substantially in parallel with the first end surface 23a of the cover plate 23, and the dicing sheet 12 is peeled off from the first end 15a side of the semiconductor die 15 up to the peel off line 53. During the above process, the semiconductor die 15 does not change the position because the semiconductor die 15 is suctioned and held by the collet 18.

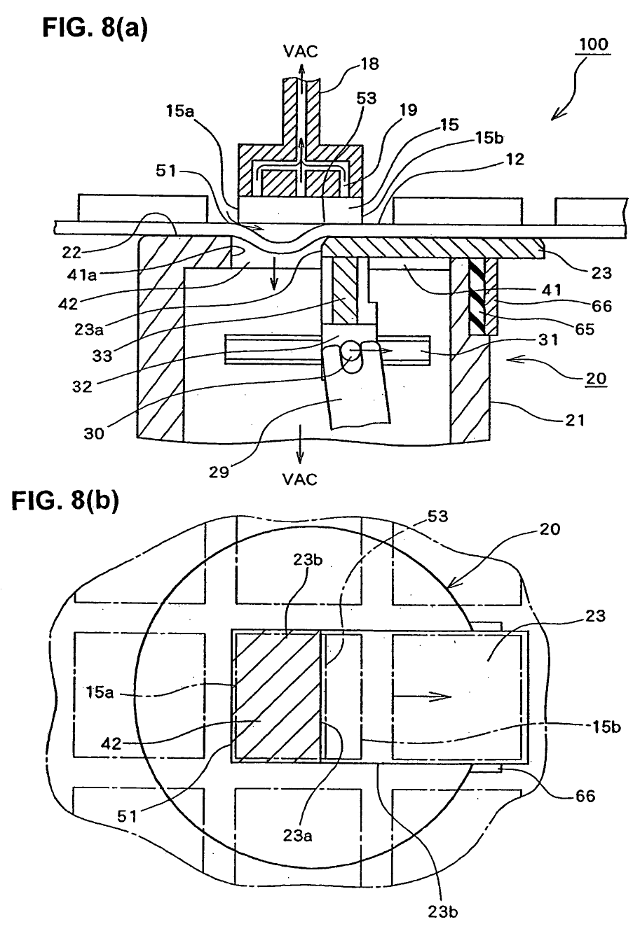

As shown in FIGS. 8(a) and 8(b), as the cover plate 23 further slides toward the outside of the die stage in which the suction window 41 extends according to an instruction from the control unit 70, the position of the first end surface 23a of the cover plate 23 is moved toward the outside of the die stage 20, and the suction opening 42 becomes larger toward the end of the die stage 20. Then, as the cover plate 23 slides further gradually, the dicing sheet 12 is sequentially suctioned into the suction opening 42 and peeled off from the semiconductor die 15 to be picked up by the suctioning, and the peel off line 53 shifts toward the outside of the die stage 20 sequentially as the cover plate 23 slides further, and then the suction opening 42 is covered by the peeled dicing sheet 12. However, even if the dicing sheet 12 is suctioned into the suction opening 42 and covers the suction opening 42, since the cover plate 23 keeps sliding toward a portion where the dicing sheet 12 is not yet peeled off, the suction of the dicing sheet 12 through the suction opening 42 is not interrupted. In this manner, an entirety of the dicing sheet 12 under the semiconductor die 15 to be picked up can be sequentially peeled off by being suctioned into the suction opening 42 without leaving an unpeeled portion.

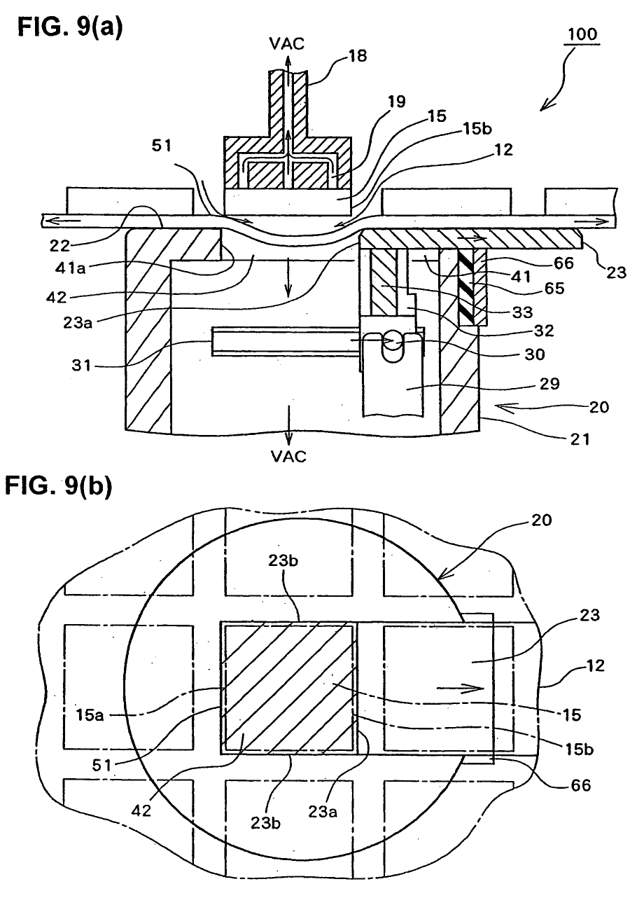

As shown in FIGS. 9(a) and 9(b), the control unit 70 has the cover plate 23 further slide using the drive unit 25 to a position at which the first end surface 23a of the cover plate 23 reaches a position passed the second end 15b of the semiconductor dies 15. As a result, the dicing sheet 12 at the second end 15b of the die 15 is suctioned into the suction opening 42 and peeled off from the semiconductor dies 15, and the air comes into between the semiconductor die 15 to be picked up and the dicing sheet 12 from the second end 15b side. Thus, the semiconductor dies 15 are completely removed from the dicing sheet 12.

After this separation, because the suction opening 42 does not increase its size anymore when the cover plate 23 is stopped to move, the dicing sheet 12 covers the suction opening 42 that is produced when the cover plate 23 stopped to move, resulting in a state that the air around the suction opening 42 cannot be suctioned through the suction opening 42 in this state.

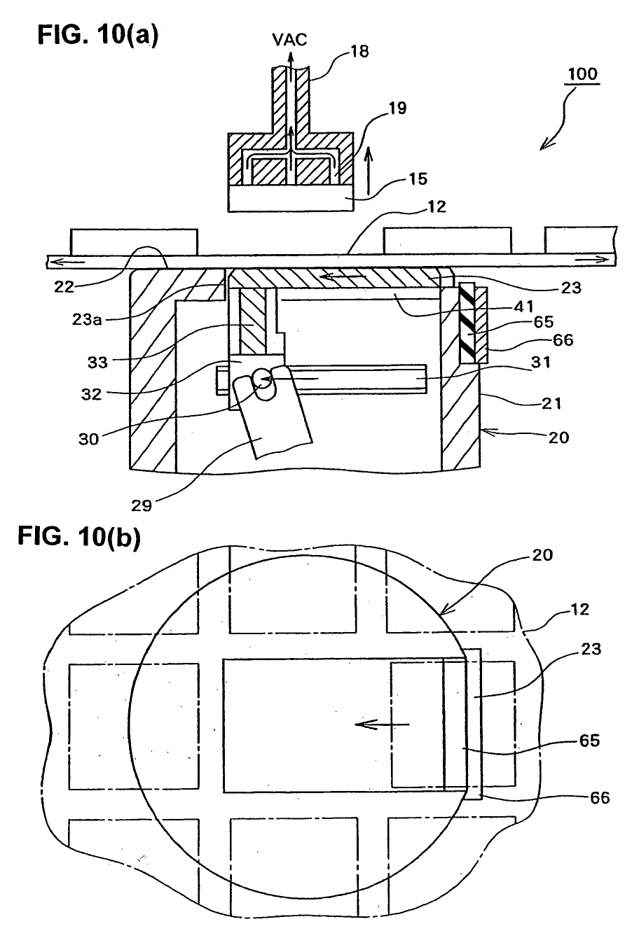

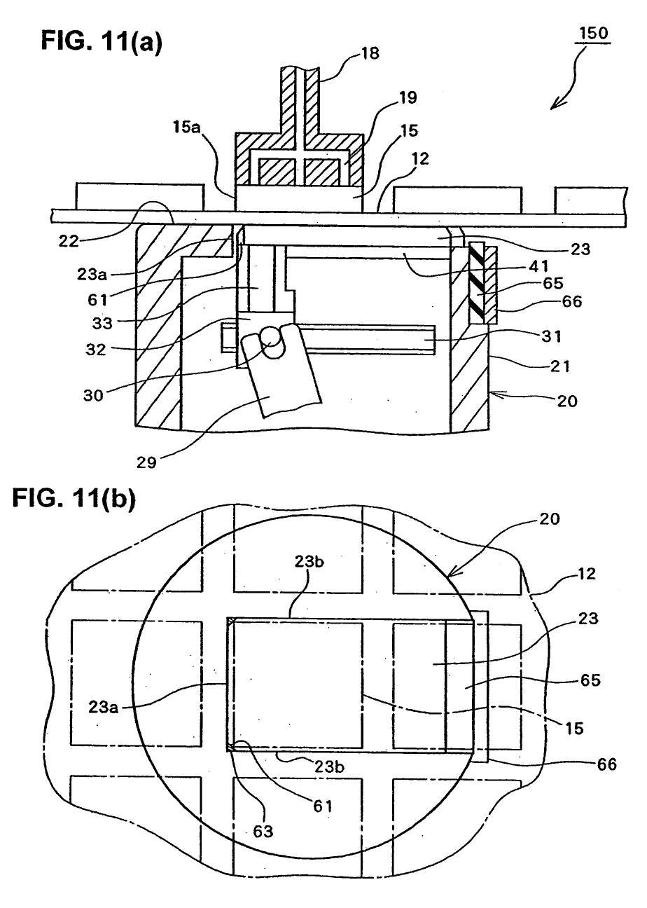

As shown in FIGS. 10(a) and 10(b), the control unit 70 then moves up the semiconductor die 15 suctioned by the collet 18 and transports the semiconductor die 15 to a succeeding step. Then, the control unit 70 disconnects between the housing 21 and the vacuum apparatus 71 to resume the housing 21 to an atmospheric pressure, and as a result, the dicing sheet 12 returns to its original flat state due to the tensile force acting toward its circumference. The control unit 70 brings back the cover plate 23 to a closed state by moving down the first link member 26 and thus moving the second link member 29 inwardly from the outside of the die stage using the drive unit 25. When the cover plate 23 is brought back to the closed state, the sealing member 65 that is compressed by the cover plate 23 until this time moves back to the initial position by its elastic force.

As described above, in this embodiment, the cover plate 23 is slid from the first end side toward the second end side of the semiconductor die 15 so as to allow the suction opening 42 to sequentially suction the dicing sheet 12 to peel off the dicing sheet 12. Accordingly, even if the suction opening 42 is covered by the dicing sheet suctioned into the suction opening 42, the cover plate 23 slides toward the portion where the dicing sheet 12 is not peeled off, and the entirety of the dicing sheet 12 can be sequentially peeled off by being suctioned into the suction opening 42. Thus, it is advantageously possible to easily peel off the entirety of the dicing sheet 12.

Moreover, an area of the dicing sheet 12 to be peeled off in a unit of time is obtained by multiplying the length of the peel off line 53 by an amount of movement of the cover plate 23 per unit time. In this case, the force required for the peeling off of the dicing sheet 12 is smaller than the force required when peeling a large portion of the semiconductor die 15 at once. Thus, it is advantageously possible to reduce the force exerted to the semiconductor die 15 when peeling the dicing sheet 12.

Further, in this embodiment, since the upper surface of the cover plate 23 and the adherence surface 22 of the die stage 20 are substantially in the same plane, the cover plate 23 is not be brought into contact with an adjacent one of the semiconductor dies 15 when sliding the cover plate 23, and the adjacent semiconductor die 15 are not damaged due to the sliding of the cover plate 23. Thus, it is advantageously possible to easily pick up the semiconductor die 15 even when there is an adjacent one of the semiconductor dies 15.

In addition, while, in this embodiment, both the suction window 41 and the cover plate 23 are substantially as wide as the semiconductor die 15 to be picked up, the widths of the suction window 41 and the cover plate 23 can be larger than that of the semiconductor die 15 to be picked up. In this case, the dicing sheet 12 is suctioned from both sides of the semiconductor die 15 into the suction opening 42, and accordingly, it is possible to suction the dicing sheet 12 into the suction opening 42 and peel the dicing sheet 12 off from the semiconductor die 15 to be picked up more effectively. Further, while, in this embodiment, the die positioning is conducted such that the first end surface 23a of the cover plate 23 is aligned with the first end 15a of the semiconductor die 15 to be picked up, as long as the semiconductor die 15 to be picked up is at the position that the semiconductor die 15 is within the upper surface of the cover plate 23, the positioning can be done such that the direction of the first end surface 23a of the cover plate 23 is aligned with the direction of the first end 15a of the semiconductor die 15, the first end 15a of the semiconductor die 15 is positioned along the direction in which the suction window 41 extends rather than the direction in which the first end surface 23a of the cover plate 23, that is, the direction in which the cover plate 23 slides. In this case, when the suction opening 42 is created by the sliding of the cover plate 23, the dicing sheet 12 between the first end 15a of the semiconductor die 15 and a semiconductor die adjacent thereto is suctioned into the suction opening 42. For this reason, the dicing sheet 12 is pulled obliquely downward at a larger angle at the first end 15a of the semiconductor die 15, and it is possible to start the peeling of the dicing sheet 12 in a smoother manner.

Moreover, in this embodiment, the die stage 20 is moved only upward and downward in the direction closer to and away from the dicing sheet 12 by the die stage vertical drive mechanism, and a mechanism for moving the die stage 20 in the horizontal direction along the dicing sheet 12 is not provided. Consequently, no backlash and such is caused by the mechanism with respect to the horizontal direction, and it is possible to realize favorable stability in the direction along the dicing sheet 12. Also, because the positioning of the semiconductor die 15 to be picked up and the cover plate 23 in the direction along the plane of the dicing sheet 12 is realized by the wafer holder horizontal drive unit 72, the position of the die stage 20 in the horizontal direction during the die positioning in the horizontal direction becomes stable. Thus, it is advantageously possible to reduce the misalignment between the cover plate 23 of the die stage 20 and the semiconductor die 15 attached to the dicing sheet 12 during the positioning.

Furthermore, in this embodiment, by way of controlling the sliding speed of the cover plate 23, it is possible to set the force exerted to the semiconductor die 15 during the peeling of the dicing sheet 12 to be suitable amount. For example, in a case in which semiconductor dies to be picked up are thin in thickness and low in strength, it is possible to easily peel off the dicing sheet by reducing the force exerted to the semiconductor dies with a weaker peeling force produced by decreasing the sliding speed of the cover plate 23 to reduce the amount of peeling per time unit to produce or a reduced suction force acting through the suction opening 42. Alternatively, in a case in which the semiconductor dies are thick and strong, it is possible to reduce the time required for the peeling off by increasing the sliding speed of the cover plate 23 to increase the area of peeling per unit time. In this case, a thickness detection unit such as a thickness sensor can be provided for detecting the thickness of the semiconductor die to be picked up and outputs data of the detected thickness to the control unit 70. It is also possible to configure that the sliding speed of the cover plate can be changed according to the thickness of the semiconductor dies detected by the thickness detection unit. In this case, the sliding speed can be determined based on a map of the sliding speed to the thickness of the semiconductor dies that is stored in a memory unit within the control unit 70. Further, in a case in which the drive unit 25 is driven by, for example, a motor, the control unit 70 can change the revolutions of the motor to change the sliding speed of the cover plate 23, or in a case in which the drive unit 25 is configured to realize the back and forth movement of the first link member 26 by the electromagnetic force, the control unit 70 can change the pulse of the electromagnetic force and an interval between the pulses to change the speed of the movement of the first link member 26.

Referring to FIGS. 11(a) and 11(b), a different embodiment according to the present invention will be described below. The like components as in the embodiment described with reference to FIG. 1 through FIG. 10(b) are designated by the like numerals and will not be explained.

In this embodiment of FIGS. 11(a) and 11(b) a notch 61 is provided at each corner between the first end surface 23a and each of the side surfaces 23b of the cover plate 23 along the suction window 41 of the cover plate 23 extending. As shown in FIG. 11(b), with the presence of the notch 61, a notch hole 63 that penetrates into the housing 21 is formed immediately below each corner on the first end 15a side of the semiconductor die 15 to be picked up when the suction window 41 is closed by the cover plate 23, and the adherence surface 22 of the die stage and the upper surface of the cover plate 23 are closely contacted to the dicing sheet 12, and when the first end 15a of the semiconductor die 15 to be picked up is positioned so as to align with the first end surface 23a of the cover plate 23.

Then, when the vacuum apparatus 71 is activated by the control unit 70 to evacuate the housing 21 to produce a vacuum therein, the dicing sheet 12 at the corners on the first end 15a side of the semiconductor die 15 are suctioned through the notch holes 63 to peel a portion at the corners first even if the cover plate 23 is in the closed state and the first end surface 23a of the cover plate 23 is in contact with the first end surface 41a of the suction window 41. After this, as in the previously described embodiment, the cover plate 23 is slid toward the outside of the die stage in the direction in which the suction window 41 extends, and the dicing sheet 12 is sequentially peeled from the first end 15a side of the semiconductor die 15.

In this embodiment, in addition to the advantages of the previously described embodiment, it is advantageously possible to peel off the dicing sheet 12 more easily than the case of the previously described embodiment. This advantage can be obtained because the dicing sheet 12 is first peeled from the corner portions of the semiconductor die 15 to form a small gap for having the air come between the dicing sheet 12 and the semiconductor die 15, then the dicing sheet 12 is sequentially peeled off, and thus the dicing sheet 12 can be peeled off smoothly as the cover plate 23 slides or is moved.

Further, while, in this embodiment, the notches are provided for the cover plate 23 and the dicing sheet 12 at the corners of the semiconductor die 15 is peeled even when the cover plate 23 is in the closed state, it is possible to provide a hole(s) that penetrates through the adherence surface 22 at the corners between the first end surface that faces the interior of the die stage of the corner of the suction window 41 and the side surfaces so as to protrude toward the outside of the suction window 41. With such a configuration, even if the cover plate 23 is in the closed state, the corner(s) of the semiconductor die 15 can be suctioned so that the dicing sheet 12 is peeled off from the corner(s) of the semiconductor die 15 first and then sequentially peeled off for its entirety.

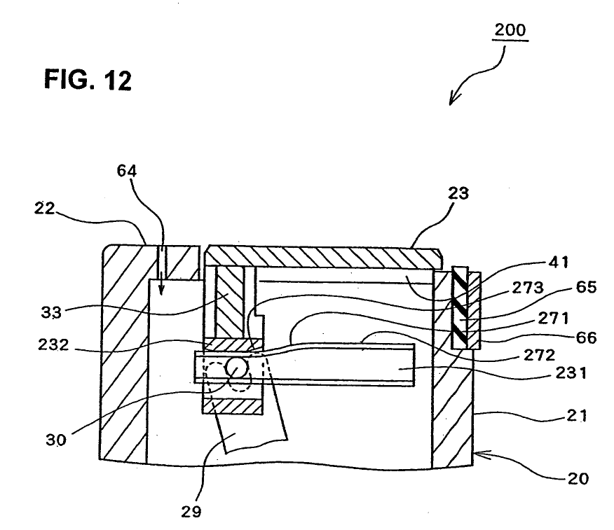

FIG. 12 shows a further different embodiment according to the present invention. The like components as in the embodiment described with reference to FIG. 1 through FIG. 10(b) are designated by the like numerals and will not be explained.

In this embodiment of FIG. 12, a cam surface 271 is provided on a guide rail 231 so that it inclines toward the adherence surface of the die stage 20. More specifically, the guide rail 231 is provided, on its adherence surface 23 side, with the cam surface 271 that is inclined obliquely upward toward the adherence surface 22 along the sliding direction of the cover plate 23 in which the suction window 41 extends, and the rail 231 is further provided, on its adherence surface 23 side, with a parallel surface 272 that extends, continuously from the cam surface 271, in parallel with the adherence surface toward the sliding direction of the cover plate 23. Further, a slider 232 is provided on the pin 30, and it is comprised of a curved surface 273 on a surface that is in contact with the guide rail 231. The curved surface 273 is brought into contact with the cam surface 271 to slide thereon. Moreover, the adherence surface 22 is provided, around the suction window 41, with a suction hole(s) 64.

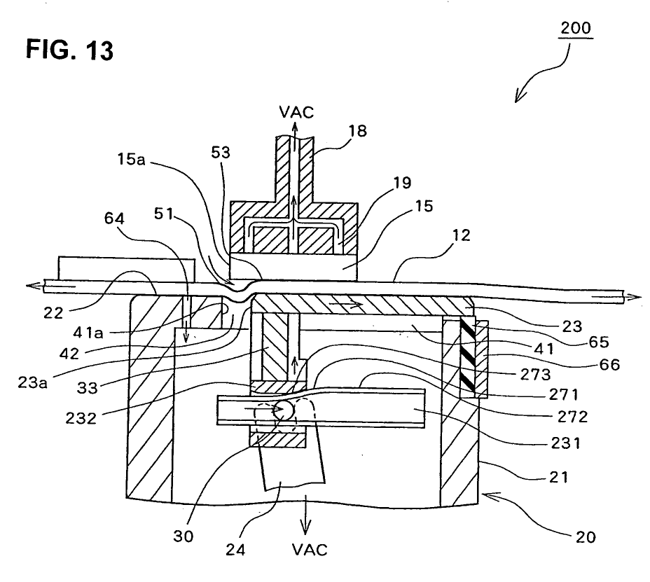

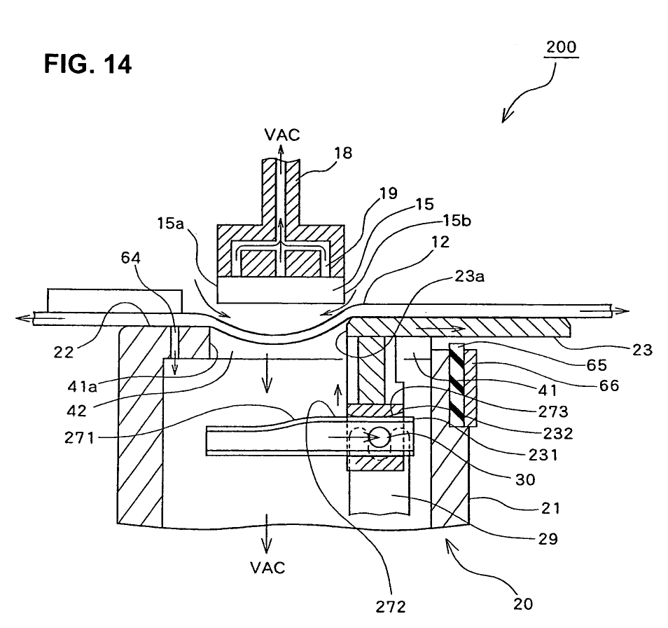

The operation according to this embodiment will be described below with reference to FIG. 13 and FIG. 14. In this embodiment, the cover plate 23 is moved to slide toward the direction in which the semiconductor die 15 has already been picked up and no semiconductor die 15 remains on the dicing sheet 12. At this time, if the semiconductor die 15 that is within the range in which the cover plate 23 is moved has already been picked up, semiconductor dies 15 outside the range in which the cover plate 23 is moved have not to be picked up. As shown in FIG. 13, the drive unit 25 operates according to the instruction from the control unit 70, and the second link member 29 is moved toward the outside of the die stage, the curved surface 273 of the slider 232 is brought into contact with the cam surface 271 of the guide rail 231. Then, as the cover plate 23 further slides or moved, the curved surface 273 of the slider 232 is gradually raised obliquely upward along the cam surface 271 of the guide rail toward the adherence surface 22. As a result, the cover plate 23 that is attached to the slider 232 via the pin 33 is moved toward the outside of the die stage to open the suction window to form the suction opening 42 and protrudes from (or protrudes higher than) the adherence surface 22, and the semiconductor die 15 to be picked up is lifted upward from the surface of the dicing sheet 12 by the protrusion of the cover plate 23. On the other hand, since the suction holes 64 are located below the semiconductor that is adjacent to the semiconductor die 15 to be picked up in the sliding direction of the cover plate 23, the dicing sheet 12 at this portion is suctioned to the adherence surface 22 through the suction holes 64.

In the above-described operation, the sealing member 65 is in contact with the bottom surface of the cover plate 23 and blocks the air entering into the housing 21; accordingly, the housing 21 is maintained under the vacuum state, and the suction opening 42 that is opened by the sliding of the cover plate 23 suctions the dicing sheet 12 to peel the dicing sheet 12 off from the semiconductor die 15. At this time, since the semiconductor die 15 is moved upward by the upward movement of the cover plate 23, and the dicing sheet 12 that is adjacent to the suction window 41 is adhere red to the adherence surface 22 via the suction holes 64, the dicing sheet 12 on the first end 15a side of the semiconductor die 15 is pulled obliquely downward toward the adherence surface 22, and the tensile force obliquely downward and the suctioning of the dicing sheet 12 into the suction opening 42 peels the dicing sheet 12 off from the semiconductor dies 15.

Then, as shown in FIG. 14, when the second link member 29 is further moved toward the outside of the die stage, the slider 232 completely climbs up the cam surface 271 and continues to slide in parallel with the adherence surface 22 along the parallel surface 272 that is continuous from the cam surface 271. In this case, since the parallel surface 272 is closer to the adherence surface 22 than the cam surface 271 is, the cover plate 23 protrudes from the adherence surface 22 more than the state shown in FIG. 13 and slides in parallel with the adherence surface 22. Then, when the first end surface 23a of the cover plate 23 reaches to a position passed the second end 15b of the semiconductor die 15, the dicing sheet 12 on the second end 15b side is peeled off, and the semiconductor die 15 are completely removed from the dicing sheet 12.

In this embodiment, the cover plate 23 slides toward the outside of the die stage while protruding from (or higher than) the adherence surface 22. Accordingly, the suctioning force through the suction opening 42 and the tensile force of the dicing sheet 12 can be utilized for peeling the dicing sheet 12 on the first end 15a side of the semiconductor die 15. Thus, it is advantageously possible to peel the dicing sheet more easily 12.

While in the previously explained embodiment, the guide rail 231 is provided with the curved surface 273 that is in contact with the cam surface 271 on the adherence surface side and moves the slider 232 along the cam surface 271. However, depending on the angle of the inclination of the cam surface 271, the slider 232 can be provided with a roller that is in contact with the cam surface 271.

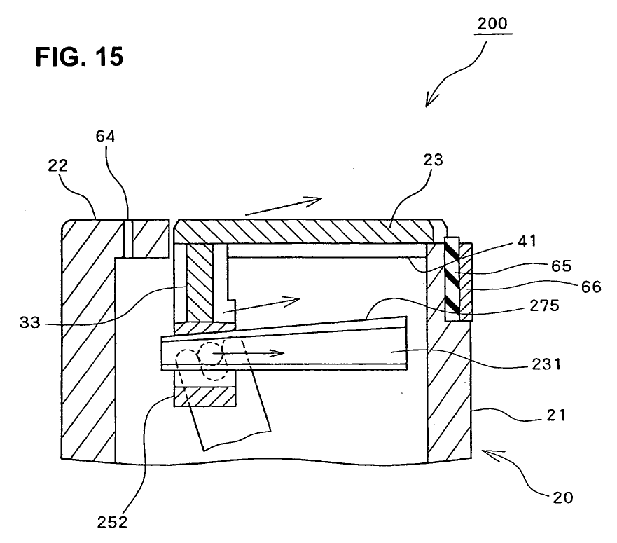

Further, while, in this embodiment, the cover plate 23 slides or is moved in parallel with the adherence surface 22 after protruded obliquely upward by the cam surface 271 and the parallel surface 272 provided on the guide rail 231 on the adherence surface side. However, the guide rail 231 can take any configuration on the adherence surface side, as long as the cover plate 23 can slide while protruding from the adherence surface 22, and it can have an inclination as shown in FIG. 15 on the adherence surface side of the guide rail 231, where the cover plate 23 can slide or is moved along the direction in which the suction window 41 extends and in which the cover plate 23 gradually rises from the die stage as the cover plate 23 slides.

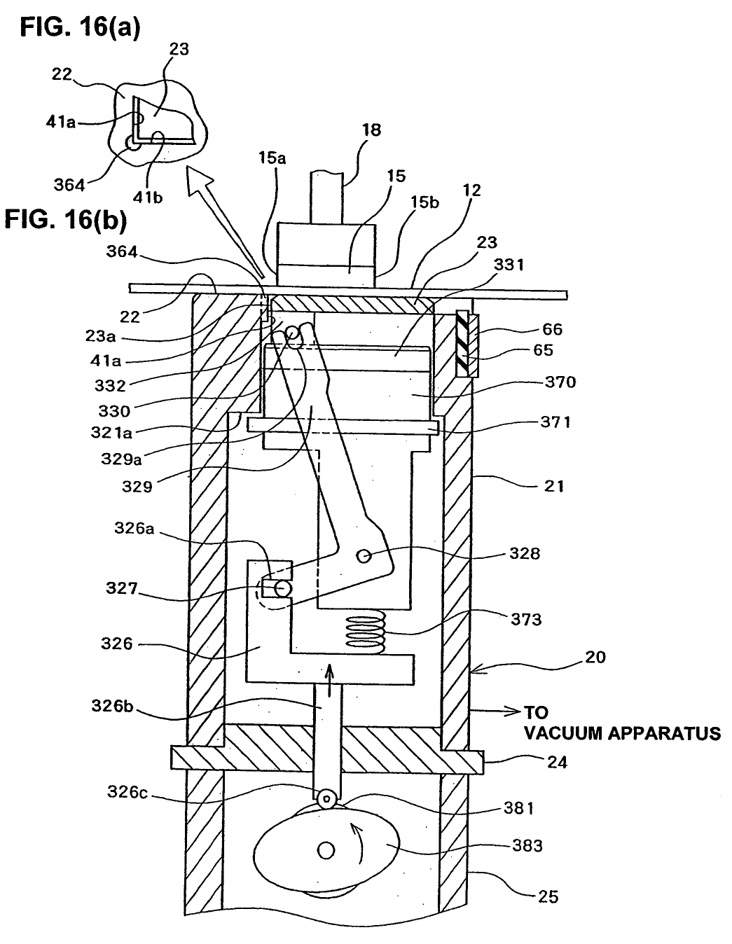

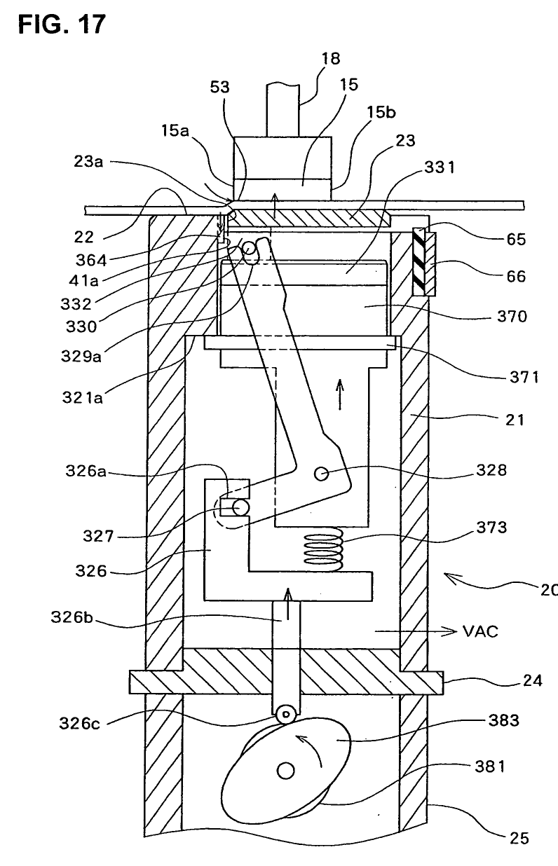

A further different embodiment according to the present invention will be described below with reference to FIG. 16 through FIG. 17. The like components as in the embodiment described with reference to FIG. 1 through FIG. 15 are designated by the like numerals and will not be explained.

As shown in FIG. 16(b), in this embodiment as in the embodiment previously described with reference to FIG. 4, the slide mechanism is provided within the die stage 20 for having the cover plate 23 slide. The slide mechanism is comprised of: a first link member 326 driven by the drive unit 25, which is provided on the base body 24 of the die stage 20, in the direction closer to and away from the adherence surface 22; a piston 370 that is slidably provided in the housing 21 of the die stage 20 and moves closer to and away from the adherence surface 22; a stopper 321a that is provided within the housing 21 and engaged with a flange 371 of the piston 370 to restrict the movement of the piston 370 in the direction closer to and away from the adherence surface 22; a spring 373 that connects the first link member 326 and the piston 370 in the direction closer to and away from the adherence surface; a guide rail 331 that is provided on the piston 370 and extends in the direction that is parallel with the adherence surface 22 and in which the suction window 41 extends; a slider 332 to which the cover plate 23 is connected and the guide rail 331 is slidably attached; and a second link member 329 that is rotatably attached to the piston 370 via a pin 328, connects the slider 332 to the first link member 326, and converts the movement of the first link member 326 in the direction closer to and away from the adherence surface 22 into the movement in the direction along the guide rail 331 of the slider 332 when the piston 370 is brought into contact with the stopper 321a. Further, the housing 21 is connected to the vacuum apparatus 71 shown in FIG. 4 so that the vacuum is produced therein.

The second link member 329 connects the slider 332 to the first link member 326 by a pin 327 provided on the first end of the second link member 329 fitted in an engagement groove 326a of the first link member 326 and by an engagement groove 329a provided on the second end of the second link member 329 and sandwiching a pin 330 of the slider 332. A motor 381 for operating the slide mechanism is provided within the drive unit 25, and a cam 383 that is in contact with a roller 326c provided on a tip end of a shaft 326b of the first link member 326 is attached to the rotary shaft of the motor 381.

FIG. 16(a), a top view, shows a flat surface of the adherence surface 22 at the corner of the suction window 41. As shown in FIG. 16(a), in this embodiment, a suction hole(s) 364 is formed at the corner (at each one of the corners) between the first end surface 41a and the side surface 41b of the suction window 41. The suction hole(s) 364 protrudes toward the outside of the suction window 41 and penetrates through the adherence surface. The suction hole(s) 364 communicates with the interior of the housing 21 even when the cover plate 23 is closed.

The operation according to this embodiment will be described below. In this embodiment, the cover plate 23 slides toward the direction where the semiconductor die 15 has already been picked up and there is no semiconductor die 15 on the dicing sheet 12. At this time, if any of the semiconductor dies 15 that is within a range in which the cover plate 23 is moved is picked up, semiconductor dies that are outside the range in which the cover plate 23 is moved are not necessarily picked up. As in the embodiment described with reference to FIG. 6, the control unit 70 starts the die positioning step, and the horizontal position of the wafer holder 10 is adjusted so that the first end surface 23a of the cover plate 23 aligns with the first end 15a of the semiconductor die 15 to be picked up, and so that the side surface of the semiconductor die 15 aligns with the side surface 23b of the cover plate 23. Then, when the die positioning step finishes, as shown in FIG. 16(b), the semiconductor die 15 comes at a position at which its first end 15a aligns with the first end surface 23a of the cover plate 23, the side surfaces of the die 15 align with the both side surfaces 23b of the cover plate 23, and the second end 15b of the semiconductor die 15 is on the cover plate 23.

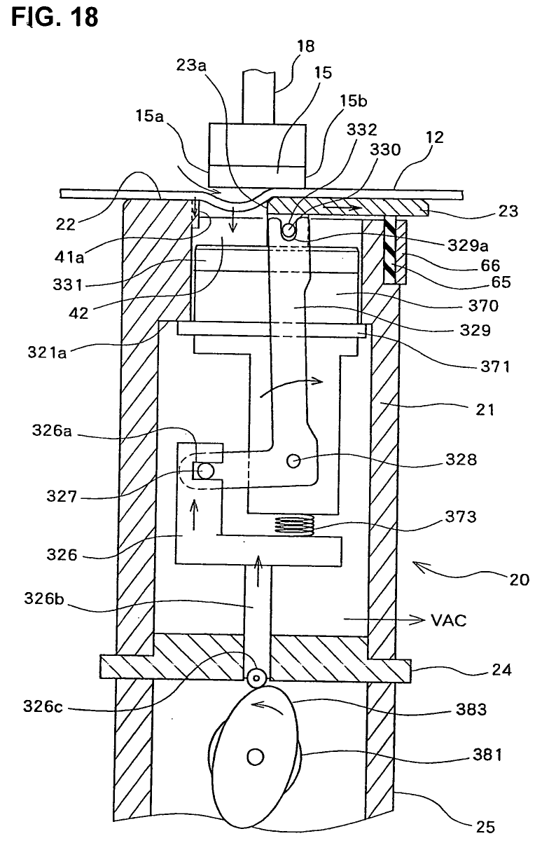

FIG. 17 through FIG. 18 show the dicing sheet peeling step. As shown in FIG. 17, at the start of the dicing sheet peeling step, the control unit 70 evacuates the interior of the housing 21 of the die stage 20 to produce a vacuum using the vacuum apparatus 71 shown in FIG. 4. Then, the control unit 70 moves the first link member 326 to protrude toward the adherence surface 22 using the drive unit 25. The operation of the wiper moving mechanism realized by the drive unit 25 will be described below.

As shown in FIG. 17, when the motor 381 of the drive unit 25 rotates according to the instruction from the control unit, the cam 383 attached to the shaft of the motor 381 rotates. The cam 383 has an ellipse shape, and its cam surface is in contact with the roller 326c provided at the tip end of the shaft 326b of the first link member 326; accordingly, when the cam 383 is rotated in a direction indicated by an arrow shown in FIG. 17, the cam surface of the cam 383 pushes the roller 326c up toward the adherence surface 22. By this movement, the shaft 326b goes upward, and an entirety of the first link member 326 is raised toward the adherence surface 22. When the entire first link member 326 is raised, the piston 370 connected to the first link member 326 on the adherence surface 22 side via the spring 373 is pushed up by the first link member 326, and the piston 370 is entirely raised toward the adherence surface 22. When the entire piston 370 is raised toward the adherence surface 22, the guide rail 331 attached to the piston 370 on the adherence surface 22 side is also raised along with the piston 370 toward the adherence surface 22. When the guide rail 331 is raised, the slider 332 that is attached so as to slide along the upper surface of the guide rail 331 is also raised toward the adherence surface 22, and as the slider 332 is raised, the surface of the cover plate 23 connected to the slider 332 protrudes upward from the adherence surface 22.

The spring 373 has a sufficient rigidity such that it hardly flexes by the force that pushes the cover plate 23 up from the adherence surface 22, and accordingly, the distance between the piston 370 and the first link member 326 practically does not change even if the cover plate 23 is pushed up from the adherence surface 22. As a result, by the rise of the first link member 326, the cover plate 23 protrudes from the adherence surface 22 without sliding.

When the upper surface of the cover plate 23 protrudes from the adherence surface, the cover plate 23 pushes the semiconductor die 15 to be picked up upward. On the other hand, the suction holes 364 are provided at the corners between the first end surface 41a and the side surfaces 41b of the suction window 41, and the dicing sheet 12 near the first end 15a of the semiconductor die 15 is suctioned and fixed to the adherence surface 22. Therefore, with the rise of the cover plate 23, the dicing sheet 12 attached to the semiconductor 15 die to be picked up is pulled toward the adherence surface 22 obliquely downward, and the tensile force the of the dicing sheet 12 obliquely downward produces a gap between the first end 15a of the semiconductor die 15 and the dicing sheet 12. Then, the air comes into the gap, and the downward tensile force and a pressure difference between the air and the vacuum inside the housing 21 causes the dicing sheet 12 to start to be peeled from the first end 15a of the semiconductor die 15. The dicing sheet 12 extends from the first end 15a of the semiconductor die 15 to the peel off line 53 that is slightly off from the first end 15a along the sliding direction.

Then, as the motor 381 is further rotated by the control unit 70, and as the first link member 326 and the piston 370 are raised toward the adherence surface 22 by the cam 383 that is rotated by the motor, the end surface of the flange 371 that extends outwardly from the piston 370 is brought into contact with the stopper 321a provided in the housing 21. As a result, the piston 370 cannot move any further toward the adherence surface 22 due to the stopper 321a, and the protrusion of the cover plate 23 from the adherence surface 22 is also stopped.

As shown in FIG. 18, when the cam 383 is further rotated and the first link member 326 is pushed up toward the adherence surface 22, the spring 373 between the piston 370 that cannot move toward the adherence surface 22 and the first link member 326 starts to be compressed by the motor 381 and cam 383 in the direction moving closer to and away from the adherence surface 22. When the spring 373 is compressed, the piston 370 does not move toward the adherence surface 22, and only the first link member 326 is moved toward the adherence surface 22. As a result, the pin 328 of the piston 370 is not raised toward the adherence surface 22, and only the pin 327 of the second link member 329 fitted in the engagement groove 326a of the first link member 326 is raised toward the adherence surface 22. As a result, the second link member 329 starts to rotate about the pin 328. By this rotary movement, the engagement groove 329a on the second end of the second link member 329 is moved toward the outside of the die stage 20, and the slider 332 to which the pin 330 fitted in the engagement groove 329a is fixed and the cover plate 23 connected to the slider 332 slide toward the outside of the die stage 20.

As the cover plate 23 slides, the first end surface 23a of the cover plate 23 is moved away from the first end surface 41a of the suction window 41, and the suction window 41 is opened to form the suction opening 42 whose width is substantially the same as the width of the semiconductor die 15 to be picked up. Since the interior of the housing 21 of the die stage 20 is under the vacuum state by the vacuum apparatus 71, the suction opening 42 suctions the dicing sheet 12 thereinto. Then, as the cover plate 23 slides, the suction opening 42 becomes wider toward the end of the die stage 20. Then, as the cover plate 23 slides, the dicing sheet 12 is sequentially suctioned into the suction opening 42 and peeled off from the semiconductor die 15 as the dicing sheet 12 is pulled into the suction opening 42. Further, the peel off line 53 sequentially is moved toward the outside of the die stage 20 as the cover plate 23 slides. Then, the suction opening 42 is covered by the dicing sheet 12 that has been peeled off. However, even if the dicing sheet 12 is suctioned into the suction opening 42 and the suction opening 42 is covered by the dicing sheet 12, since the cover plate 23 slides toward a portion where the dicing sheet 12 is not peeled yet, the suctioning of the dicing sheet 12 into the suction opening 42 never stops, and it is possible to sequentially suction the entirety of the dicing sheet 12 into the suction opening 42, so that the entire dicing sheet 12 is removed without remaining.

Moreover, when the cam 383 is further rotated, the first link member 326 is further pushed up due to the rotation of the cam 383, and the cover plate 23 slides further toward the outside of the die stage 20, as described in FIG. 14, such that the first end surface 23a of the cover plate 23 comes further outside of the second end 15b of the semiconductor die to be picked up 15, and the semiconductor die 15 is picked up by the collet 18.

After this, the shaft 326b of the first link member 326 is moved down by the rotation of the cam 383 as the cam 383 is further rotated, and by this downward movement, the cover plate 23 closes until its first end surface 23a is brought into contact with the first end surface 41a of the suction window 41. As a result, the compressing force exerted to the spring 373 is released. Then, as the cam 383 is further rotated and the shaft 326b is moved down, the piston 370, the first link member 326, and the second link member 329 are together moved downward, and the upper surface of the cover plate 23 is moved down to the position substantially the same as the surface of the adherence surface 23, thus returning to the its initial position.

In this embodiment, the cover plate 23 is caused to slide after pushing up the semiconductor die 15 to be picked up by the slide mechanism of the cover plate 23 and making a trigger for peeling the dicing sheet 12 to the first end 15a of the semiconductor die 15 by the downward tensile force exerted to the dicing sheet 12, and then the dicing sheet 12 is suctioned into the suction opening 42. Thus, it is advantageously possible to peel off the dicing sheet 12 more easily.

What is claimed is:

1. A die pick-up apparatus for picking up semiconductor dies by suctioning and holding a semiconductor die attached to a dicing sheet and picking up the semiconductor die using a collet,
the pick-up apparatus comprising:
a die stage provided with an adherence surface that is adhered to a first surface of the dicing sheet facing away from a second surface of the dicing sheet to which the semiconductor die is attached;
a suction window that is formed in the adherence surface and is larger than a semiconductor die to be picked up; and
a cover plate for opening and closing the suction window, the cover plate being provided on the die stage such that a surface of the cover plate slides along the adherence surface, and
the pick-up apparatus further comprising
a means for closely contacting the surface of the cover plate to the dicing sheet such that the semiconductor die to be picked up falls within the surface of the cover plate that closes the suction window, and
a means for sliding the cover plate to sequentially open the suction window and suctioning the dicing sheet into the opened suction window while the semiconductor die to be picked up is suctioned by the collet, thus sequentially peeling off the dicing sheet from the semiconductor die to be picked up.

2. The die pick-up apparatus for picking up semiconductor dies according to claim 1, wherein
the cover plate is provided on the die stage so as to slide along the adherence surface and protrude from the adherence surface, and
when picking up the semiconductor die, the cover plate is caused to slide while the surface of the cover plate that is closely in contact with the dicing sheet protrudes from the adherence surface.

3. The die pick-up apparatus for picking up semiconductor dies according to one of claims 1 and 2, wherein
when picking up the semiconductor die, a first end of the cover plate is aligned with a first end of the semiconductor die to be picked up, the suction window is sequentially opened by the cover plate sliding from the first end of the semiconductor die to be picked up toward a second end of the semiconductor die to be picked up, and the dicing sheet is sequentially peeled off from the semiconductor die to be picked up by sequentially suctioning the dicing sheet into the suction widow that has been opened from a first end side of the semiconductor die to be picked up.

4. The die pick-up apparatus for picking up semiconductor dies according to one of claims 1 through 3, wherein
the suction window is substantially as wide as the semiconductor die to be picked up and extends linearly from a central portion of the die stage toward outside of the die stage, and
the cover plate is a rectangular plate that is substantially as wide as the suction window.

5. The die pick-up apparatus for picking up semiconductor dies according to claim 4, wherein
a notch is formed at a corner of the cover plate between a first end surface that faces an interior of the die stage and a side surface extending in a direction in which the suction window extends.

6. The die pick-up apparatus for picking up semiconductor dies according to one of claims 1 through 5, wherein
the die stage is formed with a suction hole around the suction window in the adherence surface, and
when picking up the semiconductor die, the cover plate is caused to slide while a portion of the dicing sheet around the semiconductor die to be picked up is suctioned through the suction hole.

7. The die pick-up apparatus for picking up semiconductor dies according to one of claims 4 through 6, wherein
a sealing unit for restricting air from entering the die stage is provided on a sliding plane which is between the cover plate and the suction window.

8. The die pick-up apparatus for picking up semiconductor dies according to one of claims 1 and 3 through 7, further comprising a slide mechanism for sliding the cover plate, wherein
the slide mechanism is comprised of:
a drive unit that is attached to a base body of the die stage on a side opposite from the adherence surface and drives a first link member provided within the die stage in a direction in which the first link member is moved closer to and away from the adherence surface;
a guide rail that is provided within the die stage and extends in a direction which is substantially in parallel with the adherence surface and in which the suction window extends;
a slider to which the cover plate is connected and which is slidably provided on the guide rail; and
a second link member that is slidably provided within the die stage, connects the slider to the first link member, and converts a movement of the first link member moving closer to and away from the adherence surface into a movement of the slider moving along the guide rail, and wherein
when picking up the semiconductor die, the slide mechanism causes the cover plate to slide along the adherence surface by the first link member moving closer to and away from the adherence surface using the drive unit.

9. The die pick-up apparatus for picking up semiconductor dies according to one of claims 2 through 7, further comprising a slide mechanism for sliding the cover plate, wherein
the slide mechanism is comprised of:
a drive unit that is attached to a base body of the die stage on a side opposite from the adherence surface and drives a first link member provided within the die stage in a direction in which the first link member is moved closer to and away from the adherence surface;
a piston that is provided within the die stage and moved closer to and away from the adherence surface;
a stopper that is provided within the die stage and restricts the movement of the piston moving closer to and away from the adherence surface;
a spring that connects the first link member to the piston in the direction closer to and away from the adherence surface and is compressed when the piston is brought into contact with the stopper;
a guide rail that is attached to the piston and extends in a direction which is substantially in parallel with the adherence surface and in which the suction window extends;
a slider to which the cover plate is connected and which is slidably provided on the guide rail; and
a second link member that is slidably attached to the piston, connects the slider to the first link member, and converts a movement of the first link member moving closer to and away from the adherence surface into a movement of the slider moving along the guide rail when the piston is brought into contact with the stopper, and wherein
when picking up the semiconductor die, the slide mechanism causes the cover plate to slide along the adherence surface after the cover plate protrudes from the adherence surface by the first link member moving closer to and away from the adherence surface using the drive unit.

10. The die pick-up apparatus for picking up semiconductor dies according to one of claims 2 through 7, further comprising a slide mechanism for sliding the cover plate, wherein
the slide mechanism is comprised of:
a drive unit that is attached to a base body of the die stage on a side opposite from the adherence surface and drives a first link member provided within the die stage in a direction in which the first link member is moved closer to and away from the adherence surface;
a guide rail that is provided within the die stage, extends along the direction in which the suction window extends, and includes an inclined surface that inclines toward the adherence surface;
a slider to which the cover plate is connected and which is slidably provided on the inclined surface of the guide rail; and
a second link member that is slidably provided within the die stage, connects the slider to the first link member, and converts a movement of the first link member moving closer to and away from the adherence surface into a movement of the slider moving along the inclined surface of the guide rail, and wherein
when picking up the semiconductor die, the slide mechanism causes the cover plate to slide along the adherence surface while causing the cover plate to protrude from the adherence surface by moving the first link member closer to the adherence surface using the drive unit.

11. The die pick-up apparatus for picking up semiconductor dies according to claim 10, wherein
the inclined surface of the guide rail of the slide mechanism comprises a cam surface that faces and inclines toward the adherence surface from the central portion of the die stage to the direction in which the suction window extends, and a parallel surface that continues from the cam surface and extends in parallel with the adherence surface to the direction in which the suction window extends, and
the second link member includes one of a curved surface and a roller that is moved along shapes of the cam surface and of the parallel surface of the guide rail on the adherence surface side.

12. The die pick-up apparatus for picking up semiconductor dies according to one of claims 1 through 11, further comprising:
a die stage vertical drive mechanism that moves the die stage in a direction closer to and away from the dicing sheet; and
a wafer holder horizontal drive unit that moves a wafer holder along a surface of the dicing sheet, the wafer holder being for retaining the dicing sheet to which the semiconductor die to be picked up is attached, wherein
when picking up the semiconductor die,
the surface of the cover plate is caused to closely contact with the dicing sheet by the die stage vertical drive mechanism, and
die positioning is performed by the wafer holder horizontal drive unit so that the semiconductor die to be picked up falls within the surface of the cover plate closing the suction window.

13. A method for picking up semiconductor dies that are attached to a dicing sheet using a die pick-up apparatus comprising:
a die stage provided with an adherence surface that is adhered to a first surface of the dicing sheet facing away from a second surface of the dicing sheet to which a semiconductor die to be picked up is attached;
a suction window that is formed in the adherence surface and is larger than the semiconductor die to be picked up;
a cover plate for opening and closing the suction window, the cover plate being provided on the die stage such that a surface of the cover plate slides along the adherence surface; and
a collet for picking up a semiconductor die,
the method comprising:
a die positioning step in which the surface of the cover plate is caused to closely contact with the dicing sheet such that the semiconductor die to be picked up falls within the surface of the cover plate that closes the suction window, and
a dicing sheet peeling step in which the dicing sheet is sequentially peeled from the semiconductor die to be picked up by sliding the cover plate to sequentially open the suction window and suctioning the dicing sheet into the opened suction window while the semiconductor die to be picked up is suctioned by the collet.

14. The method for picking up semiconductor dies according to claim 13, wherein
the cover plate is provided on the die stage so as to slide along the adherence surface and protrude from the adherence surface, and
in the dicing sheet peeling step, the cover plate slides while the surface of the cover plate is being protruded from the adherence surface.

15. The method for picking up semiconductor dies according to one of claims 13 and 14, wherein
the die positioning step aligns a first end of the cover plate with a first end of the semiconductor die to be picked up, and
the dicing sheet peeling step sequentially opens the suction window by sliding the cover plate from the first end of the semiconductor die to be picked up toward a second end of the semiconductor die to be picked up and sequentially peels off the dicing sheet from the semiconductor die to be picked up by sequentially suctioning the dicing sheet into the suction window that has been opened from a first end side of the semiconductor die to be picked up.
